(19) United States
(12) Patent Application Publication
(10) Pub. No.: US 2009/0225502 A1
(43) Pub. Date: Sep. 10, 2009

(54) Display Device

(75) Inventors: Chieh-Yuan Cheng, Taoyuan County (TW); Shao-Kun Shyu, Taipei County (TW)

Correspondence Address: COVENANT IP CONSULTING CO., P.O. BOX 34-306 TAIPEI CITY, TAIPEI, 10499, TW

(73) Assignee: QISDA CORPORATION, Taoyuan County (TW)

(21) Appl. No.: 12/395,733

(22) Filed: Mar. 2, 2009

(30) Foreign Application Priority Data
Mar. 4, 2008 (TW) 097107429

(51) Int. Cl. H05K 5/00; G09F 13/08; G02F 1/1333; H04B 10/06

(52) U.S. Cl. 361/679.01; 362/97.1; 349/58; 398/106

(57) ABSTRACT

Display device of the present invention includes a housing, a display module and a signal receiver. The display module and the signal receiver are disposed in the housing. The signal receiver electrically connects to a circuit board and the signal receiver is disposed between the circuit board and the display module. The rear plate of the display module has an opening. The position of the signal receiver on the circuit board is corresponding to the position of the opening on the rear plate. Thus, the signal receiver can receive outside signals via a front opening on the housing, the display region of the display module and the opening on the rear plate.

### BACKGROUND OF THE INVENTION

1. Field of the Invention

The invention relates to a display device and, more particularly, to a display device having a signal receiver.

2. Description of the Prior Art

In recent years, display devices are widely used in consuming electronic products, such as liquid-crystal televisions, monitors or digital frames. Presently, display devices, such as TVs or digital frames, are usually equipped with signal receivers on the frame of display devices for receiving remote control signals. Usually, there is an aperture disposed on the frame of display device corresponding to the signal receiver. Additionally, there may be a transparent (or semi-transparent) material covered on the aperture. The purpose is that the signal receiver is exposed for receiving signals. However, the aperture on the frame of display device could destroy the integrity of the display device.

For example, FIG. 1A and FIG. 1B are exploded schematic view and side schematic view of display device 10 in the prior art respectively. There is an aperture 109 disposed on the frame of the display device 10 corresponding to the position of the signal receiver and the signal receiver is exposed. As shown in FIG. 1A, the display device 10 comprises a housing 101, a display module, a signal receiver and a circuit board 107. As shown in FIG. 1B, the display module 103 is disposed inside the housing 101 and the signal receiver 105 that electrically connects to the circuit board 107 is also disposed inside the housing 101. Besides, there is an aperture 109 on the frame of the housing 101 and the aperture is disposed corresponding to the position of the signal receiver 105. The signal receiver 105 is then capable of receiving outside signals, such as infrared remote control signals. However, if the display device is a digital frame, the aperture on the frame and the exposed signal receiver would destroy the integrity of the frame.

### SUMMARY OF THE INVENTION

The purpose of the invention is to provide a display device for receiving outside signals.

Another purpose of the invention is to provide complete integrity of the display device and there is no aperture corresponding to a signal receiver on the housing of the display device.

The invention relates, in one embodiment, to a display device comprising a housing, a display module and a signal receiver. The display and the signal receiver are disposed inside the housing. The signal receiver electrically connects to a circuit board and the signal receiver is disposed between the display module and the circuit board. A part of the display module is exposed to form a display region (i.e. a region for showing an image) through the front opening of the front surface of the housing. The rear plate of the display device has an opening and the position of the signal receiver on the circuit board is corresponding to the position of the opening of the rear plate. Thus, the signal receiver is capable of receiving outside signals through the front opening of the housing, the display region of the display module and the opening of the rear plate.

The signal receiver is preferably a directional signal receiver, such as an infrared signal receiver. The signal receiver is capable of receiving a directional signal within the effective receiving range. There is a particular relationship between the aperture of the opening of the rear plate and effective receiving angle so that the signal receiver can receive outside signals transmitted within the maximum effective receiving range through the opening of the rear plate.

### BRIEF DESCRIPTION OF THE APPENDED DRAWINGS

FIG. 1A is an exploded schematic diagram of a display device of the prior art.

FIG. 1B is a cross-sectional schematic diagram of a display device of the prior art.

FIG. 2 is an exploded schematic diagram of a display device, in accordance with one embodiment of the present invention.

FIG. 3 is a further exploded schematic diagram of the display device, in accordance with the embodiment of the present invention.

FIG. 4A is a further exploded schematic diagram of the display device, in accordance with the embodiment of the present invention.

FIG. 4B is a further exploded schematic diagram of the display device, in accordance with the embodiment of the present invention.

FIG. 5A is a part of cross-sectional schematic diagram of the display device; and

FIG. 5B is a perspective view of FIG. 5A.

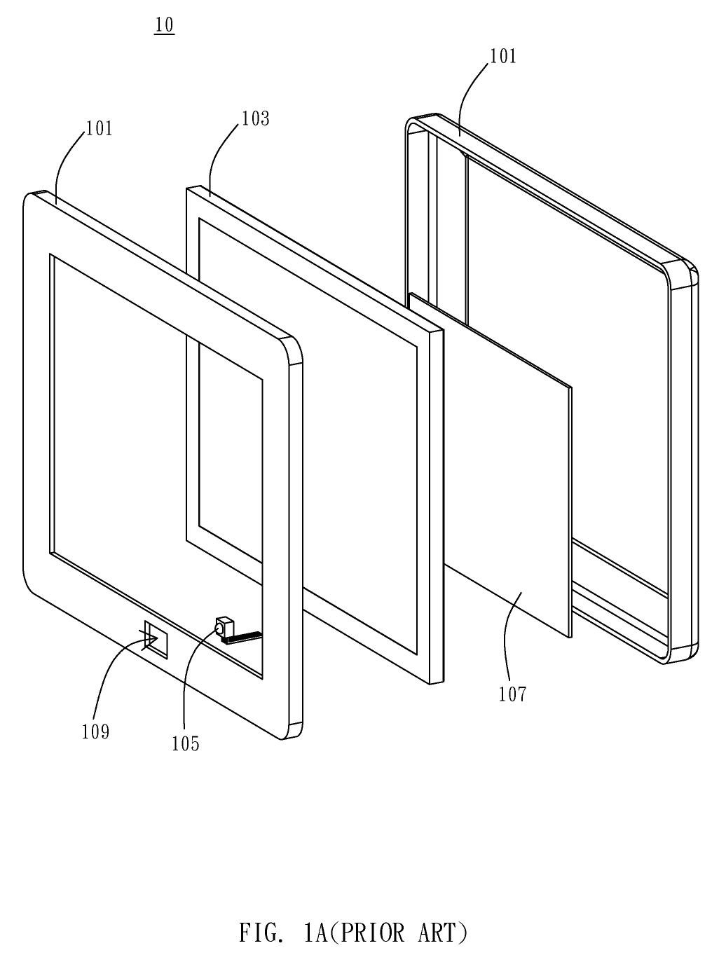

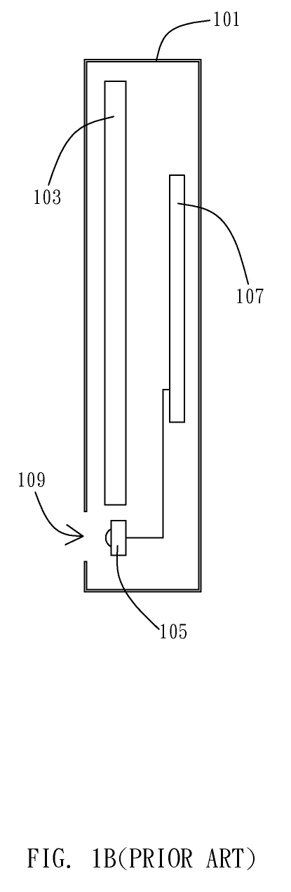

### DETAILED DESCRIPTION OF THE INVENTION

The present invention relates to display devices for receiving outside signals. Referring to the preferred embodiment, the display devices of the invention comprise televisions, personal computers, lap-top computers or digital frames, etc, which are capable of receiving remote signals. According to the embodiment of the invention, the display devices are capable of receiving remote control signal from users to change the setting or display information of the display device.

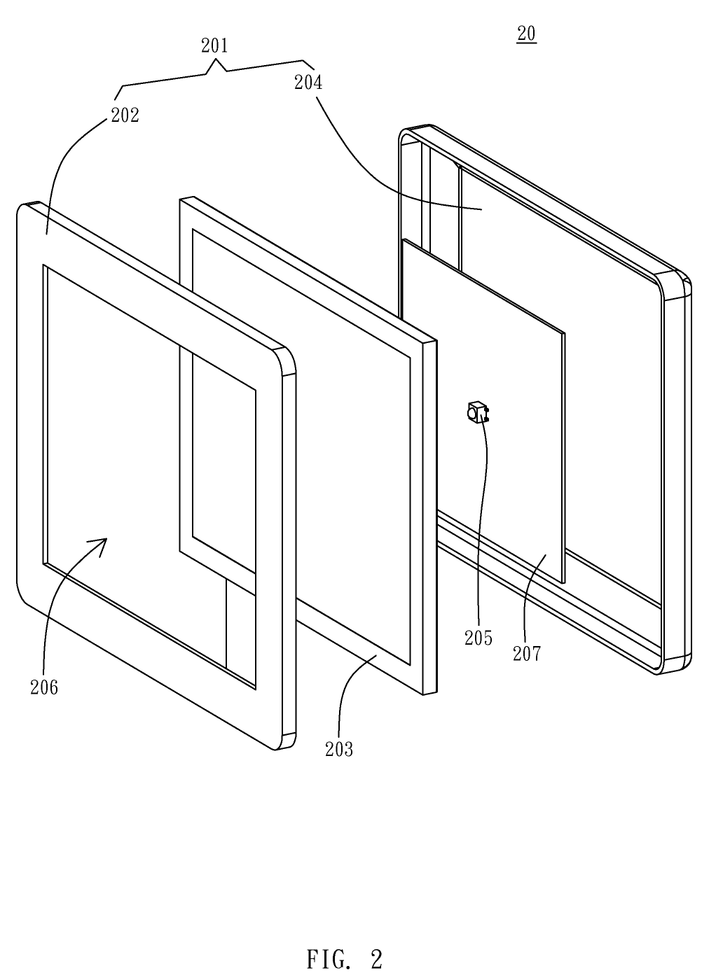

FIG. 2 is an exploded schematic diagram of a display device. The display device 20 comprises a housing 201, a display module 203 and a signal receiver 205. The display module 203 and the signal receiver 205 are disposed inside the housing 201. In detail, the housing 201 comprises a front surface 202 and a rear surface 204. The front surface 202 includes a front opening 206. The display module 203 is disposed between the front surface 202 and the rear surface 204. A part of display module is exposed through the front opening 206. The exposed part is defined as a display region that shows images.

As shown in FIG. 2, in accordance with the embodiment, the signal receiver 205 of the display device 20 is disposed between the display module 203 and rear surface 204 and the signal receiver 205 is positioned corresponding to the display region. In detail, the display device 20 of the embodiment further comprises a circuit board 207. The signal receiver 205 electrically connects to the circuit board 207. In general, the signal receiver 205 is connected to the circuit board by surface-mount technology. However, in another embodiment, the signal receiver 205 connects to the circuit board 207 by a connector. Furthermore, the position of the signal receiver 205 on the circuit board 207 is corresponding to the display region of the display module 203. Therefore, the signal receiver is capable of receiving outside signals through the display region.

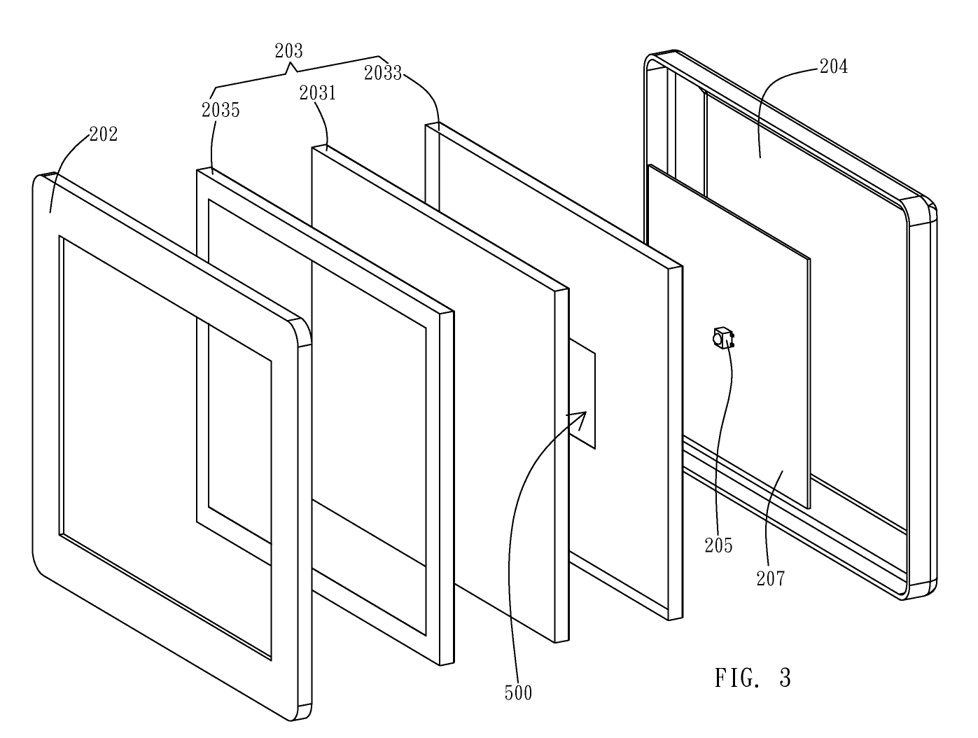

FIG. 3 is a further exploded schematic diagram of the display device, in accordance with the embodiment of the present invention, including the exploded schematic diagram of the display module 203. The display module 203 can be a liquid crystal display module. As shown in FIG. 3, the display module 203 of the embodiment comprises a display panel module 2031, a rear plate 2033 and a frame 2035. The display panel module 2031 is positioned between the rear plate 2033 and the frame 2035. The display panel module 2031 faced to the frame comprises a display region. Note that the rear plate 2033 of the display module 203 has an opening 500. The position of the opening 500 is corresponding to the area of the display region of the display panel module 2031. The position of the signal receiver 205 on the circuit board 207 is corresponding to the opening 500 of the rear plate 2033. In general, the rear plate 2033 of the display module 203 is made of metal such as iron for fixing display panel module 2031 inside the housing 201 of the display device 20. The opening 500 prevents the signals outside the housing 201 from being blocked by the rear plate 2033. Therefore, the signal receiver 205 is capable of receiving signals through display panel module 2031 and the opening 500.

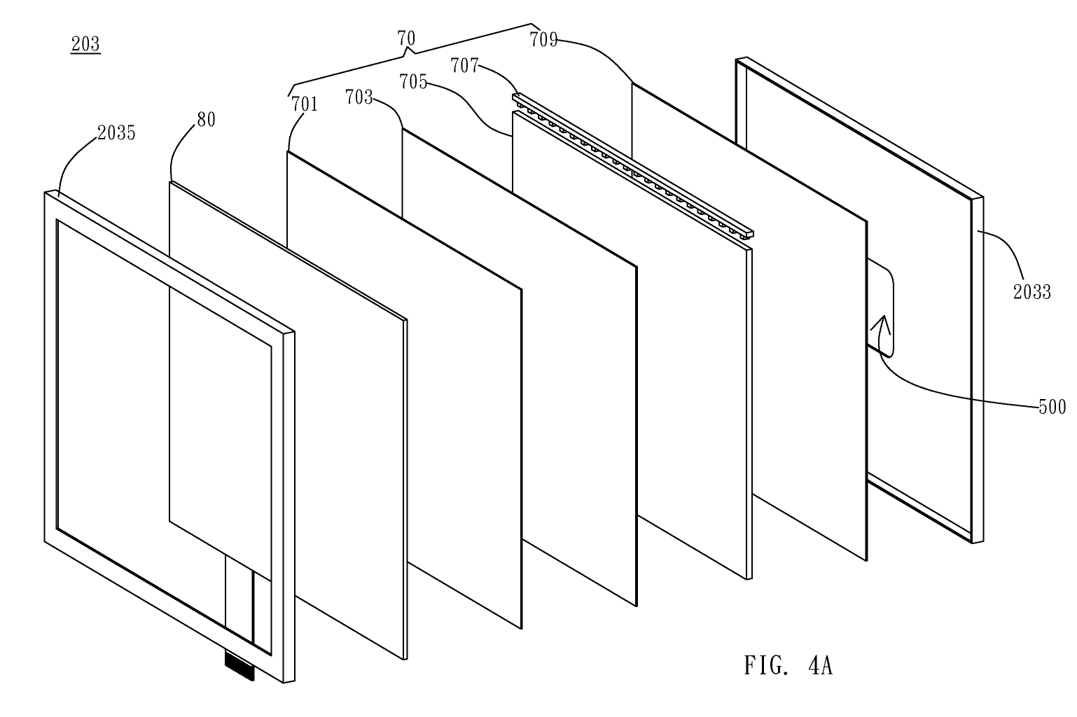

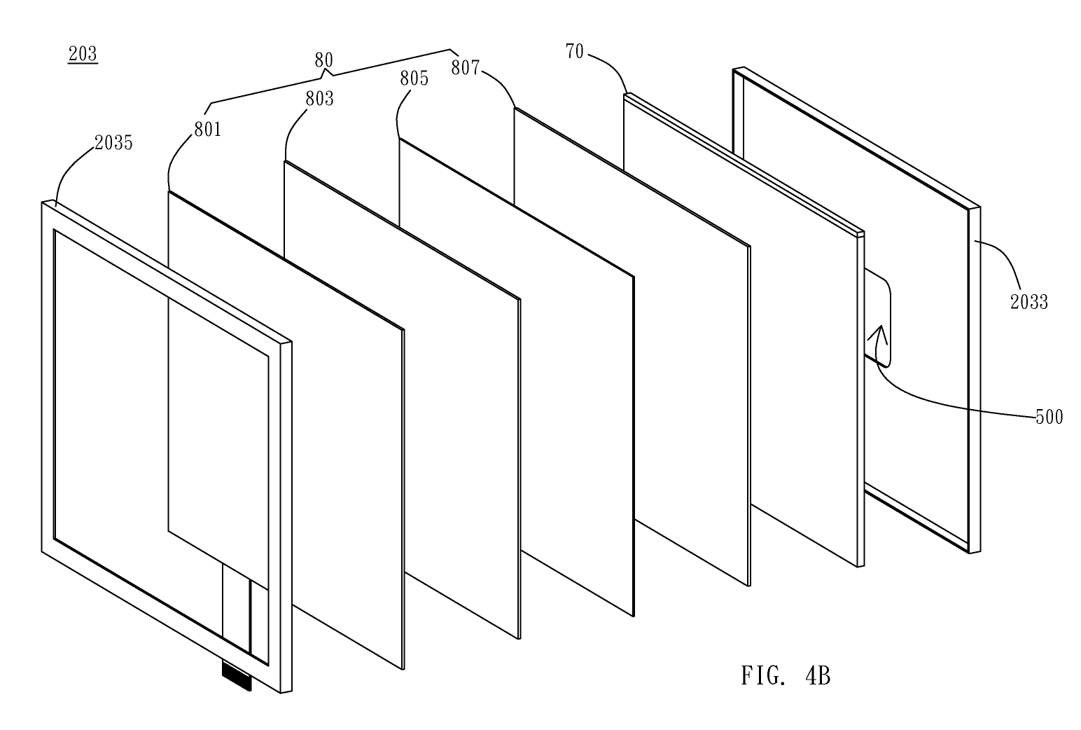

FIG. 4A is a further exploded schematic diagram of the display device, in accordance with the embodiment of the present invention, including the exploded schematic diagram of the display module 203. As shown in FIG. 4A, the display panel module 2031 of the display module 203 comprises a backlight module 70 and a display panel 80. The backlight module 70 comprises a diffuser 701, a prism sheet 703, a light guide 705, a light source module 707 and a reflector 709. The diffuser 701 and the prism sheet 703 have the property of transparency. They improve light-emitting efficiency and adjust light-emitting distribution so as to uniform the light. Besides, in the embodiment, the light source module 707 is disposed on one side of the light guide 705 by which the light source module 707 distributes the light uniformly on the display panel 80. The light source can be light-emitting diode (LED) or other light-emitting components, and this invention will not be limited by the kinds of the light sources. The reflector 709 reflects the light which is dissipated from the light source module 707 and light guide 705 back to light guide 705 to increase light-emitting efficiency.

FIG. 4B is a further exploded schematic diagram of the display device, in accordance with the embodiment of the present invention. As shown in FIG. 4B, the display panel 80, in the embodiment, is a liquid crystal display panel. Specifically, in FIG. 4B, the display panel 80 comprises a polarizer 801, an upper substrate 803, an optical film 805 and a lower substrate 807. The upper substrate 803 is next to the polarizer 801. The optical film 805 is disposed between the upper substrate 803 and lower substrate 807. The lower substrate 807 has active array components, such as thin-film transistors array structure. The liquid crystal is filled between the optical film 805 and lower substrate 807. The polarizer 801 ensures the direction of light-emitting. The upper substrate 803 and lower substrate 807 are made of transparent material, such as transparent glass. The optical film 805 is made of optical plastic material, such as light filters and protection films. In other examples, the display panel 80 can be other kinds of display panels, such as an organic light-emitting diode panel.

The signal receiver 205 of the display device 20 described in the previous embodiment of the invention is a directional signal receiver for receiving directional wireless signals, such as infrared signals. The directional signal receiver 205 is usually limited by an effective receiving range based on effective receiving angle 2θ when the directional signal receiver 205 receive signals. If the outside signals are transmitted within the effective receiving range, the signal receiver 205 can receive the outside signals. However, in other embodiments, the signal receiver is not limited to the directional signal receiver and it can be any kind of wireless remote control signal receivers, such as a radio frequency remote control receiver.

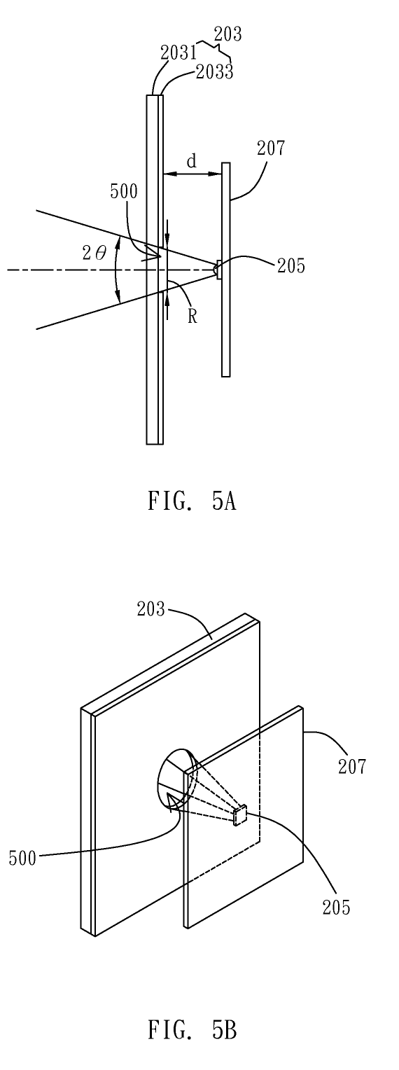

FIG. 5A is a part of cross-sectional schematic diagram of the display device 20 illustrating the positions of the display module 203, the signal receiver 205 and the circuit board 207. As shown in FIG. 5A, the size of the opening 500 on the rear plate 2033 of the display module 203 is preferably designed so that the effective receiving angle of signal receiver 205 is equal to or greater than 2θ. Thus, the directional signals are received by signal receiver 205 through the opening 500 instead of being blocked by the rear plate 2033. Because the signal receiver 205 is disposed on the circuit board 207, there is a distance d between the signal receiver 205 and the opening 500 of the rear plate 2033. The size of the opening 500 is preferably designed to cover the effective receiving range of the signal receiver 205 by establishing a relationship among the aperture of the opening 500, the distance d and the effective receiving angle 2θ. For example, the shape of the opening 500 is round in this embodiment, but in this invention the shape of the opening 500 is not limited. The aperture diameter R of the opening 500 is preferably larger than the product of tangent θ (θ is a half of effective receiving angle 2θ) and two times the distance d, i.e. R>=2d×tan θ. Besides, as shown in FIG. 5B, in this embodiment, a hypothetical cone may be formed by the range extending outward from the signal receiver 205 based on effective receiving angle 2θ. Thus, the size of the aperture of the opening 500 is preferably larger than the area in the rear plate 2033 with which the hypothetical cone intersects. In other embodiments, aforementioned relationship does not necessarily exist among the opening, the effective receiving angle and the distance. For example, the opening of the rear plate can be smaller than the opening described in the previous embodiment, but the signal receiver accordingly could not receive some of the signals which are transmitted within the effective receiving range. It depends on the requirements of the designer and the product specifications.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A display device, comprising:
a housing comprising a front surface and a rear surface, the front surface having a front opening;
a display module disposed in the housing, the display module comprising a display region which is exposed in the front opening of the front surface; and
a signal receiver disposed between the display region and the rear surface, for receiving a signal from outside the housing through the display region.

2. The display device of claim 1, wherein the display module further comprises a display panel module and a rear plate, and the display panel module is disposed on the rear plate and toward the front opening of the front surface.

3. The display device of claim 2, wherein the rear plate has an opening, the signal receiver is disposed corresponding to the position of the opening for receiving the signal through the display panel module.

4. The display device of claim 3, wherein the signal receiver comprises a directional signal receiver, the signal is a directional wireless signal, the directional signal receiver receives the directional wireless signal, the signal receiver has an effective receiving range, and the opening of the rear plate is larger than an area in the rear plate on which the effective receiving range is projected.

5. The display device of claim 3, wherein the signal receiver comprises a directional signal receiver, the signal is a directional wireless signal, the directional signal receiver receives the directional wireless signal, the signal receiver has an effective receiving angle 2 θ, a distance d is disposed between the opening and the signal receiver, and the aperture diameter of the opening is larger than the 2d tan θ.

6. The display device of claim 2, wherein the rear plate is made of metal.

7. The display device of claim 2, wherein the display panel module comprises a display panel and a backlight module, and the signal transmits through the display panel and the backlight module to the signal receiver.

8. The display device of claim 7, wherein the backlight module comprises a light source module, a diffuser, a prism sheet, a light guide and a reflector.

9. The display device of claim 7, wherein the display panel comprises a polarizer, an upper substrate, an optical film and a lower substrate.

10. The display device of claim 9, wherein display module is a liquid crystal display module.

11. The display device of claim 1, further comprising a circuit board disposed between the display module and rear surface, the signal receiver being electrically connected to the circuit board to transmit the signal received from the signal receiver to the circuit board.

12. The display device of claim 11, wherein the signal receiver is connected to the circuit board by surface-mount technology.

13. The display device of claim 11, wherein the signal receiver is connected to the circuit board by a connector.

14. The display device of claim 1, wherein the signal receiver comprises a wireless signal receiver, the signal is a wireless signal and the wireless signal receiver receives the wireless signal.

15. The display device of claim 1, wherein the signal receiver comprises a remote control signal receiver, the signal is a remote control signal and the remote control signal receiver receives the remote control signal.

16. The display device of claim 1, wherein the signal receiver comprises a directional signal receiver, the signal is a directional wireless signal and the directional signal receiver receives the directional wireless signal.

17. The display device of claim 16, wherein the directional signal receiver comprises an infrared signal receiver, the directional wireless signal is an infrared signal and the infrared signal receiver receives the infrared signal.
